(19) United States
(12) Patent Application Publication
(10) Pub. No.: US 2025/0107054 A1
(43) Pub. Date: Mar. 27, 2025

(54) Electronic Device with Housing Slot Antennas

(71) Applicant: Apple Inc., Cupertino, CA (US)

(72) Inventor: Paul X Wang, Cupertino, CA (US)

(21) Appl. No.: 18/777,404

(22) Filed: Jul. 18, 2024

Related U.S. Application Data
(60) Provisional application No. 63/584,851, filed on Sep. 22, 2023.

(51) Int. Cl. H05K 7/20; G06F 1/16; H01Q 1/27; H01Q 13/10; H04N 23/90

(52) U.S. Cl. CPC H05K 7/20972; G06F 1/163; H01Q 1/273; H01Q 13/10; H04N 23/90

(57) ABSTRACT

An electronic device such as a head-mounted display device may include an outer conductive chassis and wireless circuitry. The wireless circuitry may include an antenna. The antenna may have an antenna resonating element formed from a slot in the conductive chassis. The antenna may have antenna feed terminals coupled to the conductive chassis on opposing sides of the slot. The slot may form a thermal vent, a sensor window, a charging port, a card port, an acoustic port, or a button opening for the device, as examples.

This application claims the benefit of U.S. Provisional Patent Application No. 63/584,851, filed Sep. 22, 2023, which is hereby incorporated by reference herein in its entirety.

### FIELD

This relates generally to electronic devices, including electronic devices with wireless communications capabilities.

### BACKGROUND

Electronic devices often have displays that are used to display images to users. Such devices can include head-mounted displays and can have wireless circuitry with antennas.

If care is not taken, head-mounted displays can be subject to excessive thermal loads. It can also be challenging to incorporate antennas that exhibit satisfactory levels of wireless performance into head-mounted displays.

### SUMMARY

A head-mounted device may have a housing. The housing may have an inner conductive chassis mounted to an outer conductive chassis. A logic board may be mounted to the inner conductive chassis. Left and right displays may be mounted to the logic board and may display images at a rear of the device. A cover may be mounted to the outer conductive chassis at the front of the device. The cover may have a compound or three-dimensional curvature. A front-facing display may be mounted to the cover and may display images through the cover.

The device may have wireless circuitry with an antenna. The antenna may have an antenna resonating element formed from one or more slots in the outer conductive chassis. The antenna may have an antenna feed coupled to the outer conductive chassis across the slot. The slot may form a thermal vent, a sensor window, a charging port, a card port, an acoustic port, or a button opening for the device, as examples.

An aspect of the disclosure provides a head-mounted device. The head-mounted device can include a first conductive chassis. The head-mounted device can include a logic board mounted to the first conductive chassis. The head-mounted device can include first and second displays mounted to the logic board and configured to display respective left and right images. The head-mounted device can include a second conductive chassis that extends around the first conductive chassis and the logic board. The head-mounted device can include a cover mounted to the second conductive chassis opposite the first and second displays, the cover having a third display configured to display images through the cover. The head-mounted device can include an antenna having an antenna resonating element formed from a slot in the second conductive chassis.

An aspect of the disclosure provides an electronic device. The electronic device can include a conductive housing. The electronic device can include a vent in the conductive housing. The electronic device can include a fan configured to convey air through the vent. The electronic device can include an antenna having antenna feed terminals coupled to the conductive housing on opposing sides of the vent.

An aspect of the disclosure provides an electronic device. The electronic device can include a conductive housing extending around a periphery of the electronic device. The electronic device can include a display mounted to the conductive housing. The electronic device can include a dielectric window in the conductive housing. The electronic device can include a first image sensor overlapping the dielectric window and configured to capture first image sensor data through the dielectric window. The electronic device can include a second image sensor overlapping the dielectric window and configured to capture second image sensor data through the dielectric window. The electronic device can include an antenna having antenna feed terminals coupled to the conductive housing on opposing sides of the dielectric window.

### BRIEF DESCRIPTION OF THE DRAWINGS

FIG. 1 is a schematic diagram of components in an illustrative electronic device in accordance with some embodiments.

FIG. 2 is a cross-sectional top view of an illustrative electronic device in accordance with some embodiments.

FIG. 3 is a schematic diagram of illustrative wireless circuitry having an antenna in accordance with some embodiments.

FIG. 4 is a circuit diagram of illustrative wireless circuitry having transceivers that convey radio-frequency signals using antennas in accordance with some embodiments.

FIG. 5 is a schematic diagram of an illustrative antenna having a closed slot antenna resonating element in accordance with some embodiments.

FIG. 6 is a schematic diagram of an illustrative antenna having an open slot antenna resonating element in accordance with some embodiments.

FIG. 7 is a perspective view of an illustrative electronic device having a slot antenna formed from a thermal vent in an outer chassis in accordance with some embodiments.

FIG. 8 is a cross-sectional side view showing how an illustrative slot antenna formed from a thermal vent in an outer chassis may be fed by a conductive spring in accordance with some embodiments.

FIG. 9 is a top view of an illustrative slot antenna formed from a thermal vent in an outer chassis in accordance with some embodiments.

FIGS. 10 and 11 are diagrams of an illustrative slot antenna formed from multiple thermal vents in an outer chassis in accordance with some embodiments.

FIG. 12 is a perspective view of an illustrative electronic device having a slot antenna formed from a sensor window in an outer chassis in accordance with some embodiments.

FIG. 13 is a top view of an illustrative slot antenna having different portions with different widths for accommodating sensors in accordance with some embodiments.

FIG. 14 is a perspective view showing how an illustrative slot antenna may be formed from different types of slots in an outer chassis in accordance with some embodiments.

### DETAILED DESCRIPTION

Electronic devices may be provided with components such as antennas. The electronic devices may include portable electronic devices, wearable devices, desktop devices, embedded systems, and other electronic equipment. Illustrative configurations in which the electronic devices include a head-mounted device may sometimes be described herein as an example. The head-mounted device may have first and second rear-facing displays and a front-facing display. The device may have a housing with a cover at a front side of the device. The cover may have a compound three-dimensional curvature. The device may include an outer conductive chassis and an inner conductive chassis. A main logic board may be mounted to the inner conductive chassis. The first and second rear-facing displays may be mounted to the logic board.

The device may include wireless circuitry with an antenna. The antenna may have an antenna resonating element formed from one or more slots in the outer conductive chassis. The antenna may have an antenna feed coupled to the outer conductive chassis across the slot. The slot may form a thermal vent, a sensor window, a charging port, a card port, an acoustic port, or a button opening for the device, as examples.

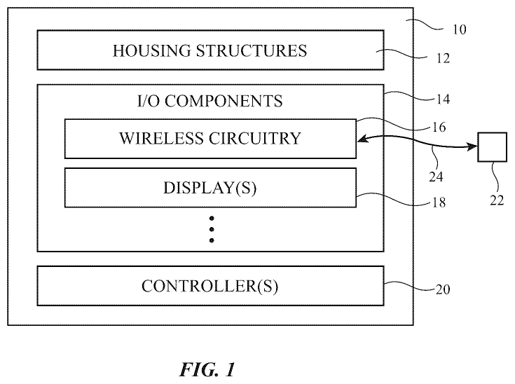

FIG. 1 shows an illustrative electronic device 10. Device 10 may be operated in a system that includes external equipment 22 other than device 10. In some implementations that are described herein as an example, device 10 may include a head-mounted device (sometimes referred to herein as a head-mounted display device or simply a head-mounted display). If desired, device 10 may include a portable electronic device such as a laptop computer, a tablet computer, a media player, a cellular telephone, or a wearable electronic device such as a wristwatch, a pendant or bracelet, headphones, an earpiece, a headset, or other small portable device. Device 10 may also be larger device such as a desktop computer, display with or without an integrated computer, a set-top box, or a wireless access point or base station. If desired, device 10 may be integrated into a larger device or system such as a piece of furniture, a kiosk, a building, or a vehicle.

As shown in FIG. 1, device 10 may include a housing formed from one or more housing structures 12 (sometimes referred to herein as housing members 12). In implementations where device 10 is a head-mounted device, housing structures 12 may include support structures that are mountable or wearable on a user's head (sometimes referred to herein as head-mounted support structures), thereby allowing a user to wear device 10 while using or operating device 10.

The head-mounted support structures in housing structures 12 may have the shape of glasses or goggles and may support one or more lenses that align with one or more of the user's eyes while the user is wearing device 10. The head-mounted support structures in housing structures 12 may include one or more rigid frames that help to provide mechanical integrity, rigidity, and/or strength to device 10 during use. In some implementations that are described herein as an example, the one or more rigid frames are formed from conductive material. The rigid frame(s) may therefore sometimes be referred to herein as conductive frame(s).

If desired, housing structures 12 may include other housing structures or housing members disposed on (e.g., layered on or over, affixed to, etc.) and/or overlapping some or all of the conductive frame(s) (e.g., dielectric structures, rubber structures, ceramic structures, glass structures, fiber composite structures, foam structures, sapphire structures, plastic structures, cosmetic structures, etc.). These other housing structures may, for example, support one or more components in device 10, may help to protect the components of device 10 from damage or contaminants, may help to allow device 10 to be worn comfortably on the user's head, may help to hide portions of the conductive frame from view, may contribute to the cosmetic or aesthetic appearance of device 10, etc.

Device 10 may include input/output (I/O) components such as I/O components 14. I/O components 14 may allow device 10 to provide output and/or other information to the user of device 10 or other entities and/or may allow device 10 to receive user input and/or other information from the user and/or other entities. I/O components 14 may include one or more displays such as displays 18. Displays 18 may emit light (sometimes referred to herein as image light) that is provided to the user's eyes for viewing. The light may contain images. The images may contain image pixels. Many images may be provided over time in a sequence (e.g., as a video). The displays 18 in device 10 may include, for example, left and right displays. The left display may provide light to a user's left eye whereas the right display may provide light to the user's right eye while the user wears device 10 on their head.

I/O components 14 may also include wireless circuitry such as wireless circuitry 16 (sometimes referred to herein as wireless communication circuitry 16). Wireless circuitry 16 may transmit radio-frequency signals 24 to external equipment 22 and/or may receive radio-frequency signals 24 from external equipment 22. External equipment 22 may include another device such as device 10 (e.g., another head-mounted device, a desktop computer, a laptop computer, a cellular telephone, a tablet computer, a tethered computer, etc.), a peripheral device or accessory device (e.g., a user input device, a stylus, a device that identifies user inputs associated with gestures or motions made by a user, a gaming controller, headphones, etc.), remote computing equipment such as a remote server or cloud computing segment, a wireless base station, a wireless access point, and/or any other desired equipment with wireless communications capabilities. In implementations that are described herein as an example, external equipment 22 includes at least first and second peripheral devices such as left and right headphone speakers or earbuds. The earbuds may be worn by a user to provide audio content to the user's ears while the user is wearing device 10 on their head. Wireless circuitry 16 may transmit the audio content to the earbuds using radio-frequency signals 24.

I/O components 14 may also include other components (not shown) such as sensors, haptic output devices (e.g., one or more vibrators), non-display light sources such as light-emitting diodes, audio devices such as speakers for producing audio output, wireless charging circuitry for receiving wireless power for charging a battery on device 10 and/or for transmitting wireless power for charging a battery on other devices, batteries and/or other energy storage devices, buttons, mechanical adjustment components (e.g., components for adjusting one or more housing structures 12 to allow device 10 to be worn comfortably on a user's head and/or on other user's heads, which may have different geometries), and/or other components.

Sensors in I/O components 14 may include image sensors (e.g., one or more visible and/or infrared light cameras, binocular three-dimensional image sensors that gather three-dimensional images using two or more cameras in a binocular configuration, sensors that emit beams of light and that use two-dimensional image sensors to gather image data for three-dimensional images from light spots that are produced when a target is illuminated by the beams, light detection and ranging (lidar) sensors, etc.), acoustic sensors such as microphones or ultrasonic sensors, gaze tracking sensors (e.g., an optical system that emits one or more beams of infrared light that are tracked using the image sensor after reflecting from a user's eyes while wearing device 10), touch sensors, force sensors (e.g., capacitive force sensors, strain gauges, resistive force sensors, etc.), proximity sensors (e.g., capacitive proximity sensors and/or optical proximity sensors), ambient light sensors, contact sensors, pressure sensors, moisture sensors, gas sensors, magnetic sensors, motion sensors for sensing motion, position, and/or orientation (e.g., gyroscopes, accelerometers, compasses, and/or inertial measurement units (IMUs) that include two or more of these), and/or any other desired sensors.

Device 10 may also include one or more controllers 20 (sometimes referred to herein as control circuitry 20). Controller(s) 20 may include processing circuitry and storage circuitry. The processing circuitry may be used to control the operation of device 10 and may include one or more processors such as microprocessors, digital signal processors, microcontrollers, host processors, application specific integrated circuits, baseband processors, graphics processing units, central processing units (CPUs), etc. The storage circuitry in controller(s) 20 may include one or more hard disks or hard drives storage, nonvolatile memory (e.g., electrically-programmable-read-only memory configured to form a solid-state drive), volatile memory (e.g., static or dynamic random-access-memory), etc. If desired, controller(s) 20 may be configured to perform operations in device 10 using hardware (e.g., dedicated hardware or circuitry), firmware, and/or software. Software code for performing operations in device 10 may be stored on storage and may be executed by processing circuitry in controller(s) 20.

Controller(s) 20 run software on device 10 such as one or more software applications, internet browsers, gaming programs, voice-over-internet-protocol (VOIP) telephone call applications, social media applications, driving or navigation applications, email applications, media playback applications, operating system functions, etc. To support interactions with external equipment 22, controller(s) 20 may implement one or more communications protocols associated with (wireless) radio-frequency signals 24. The communications protocols may include internet protocols, wireless local area network protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols, cellular telephone protocols, multiple-input and multiple-output (MIMO) protocols, antenna diversity protocols, satellite navigation system protocols, IEEE 802.15.4 ultra-wideband communications protocols or other ultra-wideband communications protocols, non-Bluetooth protocols for ultra-low-latency audio streaming, etc. Each communications protocol may be associated with a corresponding radio access technology (RAT) that specifies the physical connection methodology used in implementing the protocol.

During operation, wireless circuitry 16 may be used to support communication between device 10 and external equipment 22 (e.g., using radio-frequency signals 24). For example, device 10 and/or external device 22 may transmit video data, application data, audio data, user input commands, and/or other data to each other (e.g., in one or both directions). If desired, device 10 and/or external equipment 22 may use wired and/or wireless communications circuitry to communicate through one or more communications networks (e.g., the internet, local area networks, etc.). If desired, device 10 may communicate with other end hosts over the internet via radio-frequency signals 24 and external equipment 22. Wireless circuitry 16 may allow data to be received by device 10 from external equipment 22 and/or to provide data to external equipment 22.

While controller(s) 20 are shown separately from wireless circuitry 16 for the sake of clarity, wireless circuitry 16 may include processing circuitry and/or storage circuitry that forms part of controller(s) 20 (e.g., portions of controller(s) 20 may be implemented on wireless circuitry 16). As an example, controller(s) 20 may include baseband circuitry (e.g., one or more baseband processors), digital control circuitry, analog control circuitry, and/or other control circuitry that forms part of wireless circuitry 16. The baseband circuitry may, for example, access a communication protocol stack on controller(s) 20 to: perform user plane functions at a PHY layer, MAC layer, RLC layer, PDCP layer, SDAP layer, and/or PDU layer, and/or to perform control plane functions at the PHY layer, MAC layer, RLC layer, PDCP layer, RRC, layer, and/or non-access stratum layer.

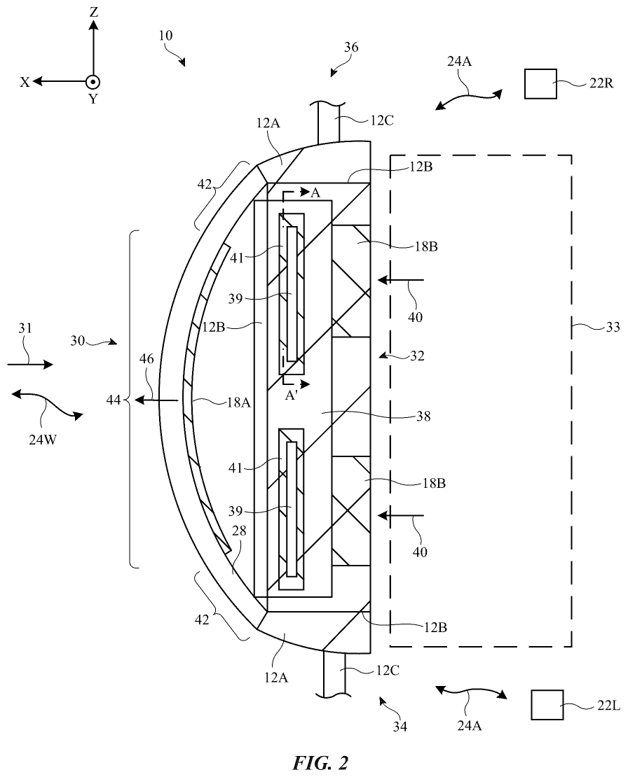

FIG. 2 is a top view of device 10. In the example of FIG. 2, device 10 is a head-mounted device. In general, device 10 may be any suitable electronic equipment. As shown in FIG. 2, device 10 may include housing structures 12. Housing structures 12 may be configured to be worn on a user's head. Housing structures 12 may have curved head-shaped surfaces, a nose-bridge portion that is configured to rest on a user's nose when device 10 is on a user's head, may have a headband such as strap 12C for supporting device 10 on the user's head, and/or may have other features that allow device 10 to be worn by a user.

Housing structures 12 may include one or more frame members such as outer chassis 12A and inner chassis 12B. Outer chassis 12A may be an outer frame surrounding the interior of device 10 and may, if desired, form exterior surfaces of device 10 (e.g., portions of outer chassis 12A may form one or more housing walls of device 10 such as housing walls that run around a periphery of device 10). Inner chassis 12B may be disposed within the interior of device 10 and may be mounted to outer chassis 12A (e.g., outer chassis 12A may surround the lateral periphery of inner chassis 12B in the X-Z plane). Strap 12C may be attached to outer chassis 12A at right side 36 of device 10 and left side 34 of device 10 (e.g., using attachment structures such as a joint, a hinge, screws, fasteners, snaps, magnets, etc.). Strap 12C may be permanently attached to outer chassis 12A or may be removable. Right side 36 may sometimes be referred to herein as right edge 36, right face 36, or right wall 36 of device 10. Left side 34 may extend opposite right side 36 and may sometimes be referred to herein as left edge 34, left face 34, or left wall 34 of device 10. Right side 36 and left side 34 may extend from front side 30 to rear side 32 of device 10.

Outer chassis 12A may be formed from conductive material such as aluminum, stainless steel, or titanium. Outer chassis 12A may therefore sometimes be referred to herein as conductive chassis 12A, conductive outer chassis 12A, outer conductive chassis 12A, conductive outer frame 12A, conductive frame 12A, conductive housing 12A, conductive outer housing 12A, or outer housing 12A. If desired, inner chassis 12B may be formed from a different conductive material than outer chassis 12A (e.g., to meet mounting requirements for the inner chassis, to meet protective requirements for the outer chassis, to meet requirements on mechanical strength and integrity, and minimize device weight). Inner chassis 12B may, for example, be formed from conductive material such as magnesium, aluminum, stainless steel, or titanium. Inner chassis 12B may therefore sometimes be referred to herein as conductive chassis 12B, conductive inner chassis 12B, inner conductive chassis 12B, conductive inner frame 12B, conductive frame 12B, conductive housing 12B, conductive inner housing 12B, inner housing 12B, or conductive support plate 12B.

Outer chassis 12A and inner chassis 12B may provide mechanical support and rigidity for device 10. In addition, one or more components within the interior of device 10 may be mounted or affixed to outer chassis 12A and/or inner chassis 12B. For example, a substrate such as logic board 38 may be mounted to inner chassis 12B. Logic board 38 may, for example, form a main logic board (MLB) for device 10. Other components in device 10 (e.g., portions of I/O components 14 and/or controller(s) 20 of FIG. 1) may be mounted to and/or formed within logic board 38. For example, one or more rear/user facing such as displays 18B may be mounted to logic board 38. Displays 18B may face rear side 32 of device 10. Rear side 32 may sometimes also be referred to herein as rear edge 32, rear wall 32, or rear face 32.

When device 10 is worn on a user's head, the user's head 33 faces rear side 32 of device 10 and the user's eyes are aligned with displays 18B, as shown by arrows 40. Displays 18B may include a left display that aligns with the user's left eye and a right display that aligns with the user's right eye (e.g., the user's left and right eyes may be located within left and right eye boxes of displays 18B). The left and right displays may include respective pixel arrays (or a single shared pixel array) and optics (e.g., one or more lenses) for directing images from the pixel arrays to the user's eyes (e.g., as binocularly fusible content).

The housing structures 12 of device 10 may also include housing structures at the front side 30 of device 10 opposite rear side 32. Front side 30 may sometimes also be referred to herein as front edge 30, front wall 30, or front face 30 of device 10. Housing structures 12 may include a cover glass assembly (CGA) 28 mounted to outer chassis 12A at front side 30 of device 10. CGA 28 may sometimes also be referred to herein as cover 28, front cover 28, or dielectric cover 28 of device 10. CGA 28 may be fully or partially transparent.

CGA 28 may include multiple layers (sometimes referred to herein as cover layers). For example, CGA 28 may include an outer cover layer for device 10 such as a glass cover layer (sometimes referred to herein as a display cover layer or a cover glass). The glass cover layer may form the exterior surface of device 10 at front side 30. CGA 28 may also include one or more dielectric layers behind and overlapping the glass cover layer (e.g., at an interior side of the glass cover layer). The dielectric layer(s) may include one or more polymer layers, plastic layers, glass layers, ceramic layers, and/or other dielectric layers. If desired, some or all of the dielectric layer(s) may be formed in a ring shape that runs along the periphery of CGA 28 in the X-Z plane and the glass cover layer (e.g., at peripheral edge portions 42 of CGA 28) or may overlap substantially all of the glass cover layer. The dielectric layer(s) behind the glass cover layer may sometimes also be referred to as a cover layer, dielectric member, dielectric cover layer, shroud, trim, and/or canopy. Peripheral edge portions 42 may sometimes also be referred to herein as peripheral region 42 or edge region 42.

CGA 28 may also include a forward-facing display such as display 18A (e.g., a flexible display panel formed from a pixel array based on organic light-emitting diodes or other display panel). CGA 28 may have a central portion or region 44 that overlaps display 18A. Peripheral edge portions 42 of CGA 28 may extend around the lateral periphery of CGA 28 and central region 44. Display 18A may emit light (e.g., images) through central region 44 of the dielectric layer(s) and the glass cover layer of CGA 28 (as shown by arrow 46) for view by persons other than the wearer of device 10. The central region 44 of the glass cover layer and the dielectric layer(s) of CGA 28 that overlap display 18A may be fully transparent or partly transparent to help hide display 18A from view when the display is not emitting light. The peripheral edge regions 42 of the glass cover layer and the dielectric layer(s) of CGA 28 may be opaque or transparent. Display 18A may sometimes be referred to herein as a front-facing display, a world-facing display, or a publicly viewable display.

Housing structures 12 may also include cosmetic covering members, polymer layers (e.g., fully or partly transparent polymer layers), and/or dielectric housing walls layered onto or over outer chassis 12A (e.g., at the exterior of device 10) if desired. Housing structures 12 may also include one or more fabric members, rubber members, ceramic members, dielectric members, curtain members, or other structures at rear side 32 of device 10 that help to accommodate the user's face while wearing device 10 and/or to block external, ambient, or scene light from the environment around the user from interfering with or washing out the light from displays 18B being viewed by the user.

Some or all of the lateral surface of CGA 28 may exhibit a curved cross-sectional profile. Within CGA 28, some or all of one or more lateral surfaces of the glass cover layer and/or some or all of one or more of the lateral surfaces of the dielectric layer(s) in CGA 28 may be characterized by a three-dimensional curvature (e.g., spherical curvature, aspherical curvature, freeform curvature, etc.). The three-dimensional curvature may be a compound curvature (e.g., the surfaces exhibiting the curvature may be non-developable surfaces).

In the areas of compound curvature, at least some portions of the curved surface(s) in CGA 28 may be characterized by a radius of curvature R of 4 mm to 250 mm, 8 mm to 200 mm, 10 mm to 150 mm, at least 5 mm, at least 12 mm, at least 16 mm, at least 20 mm, at least 30 mm, less than 200 mm, less than 100 mm, less than 75 mm, less than 55 mm, less than 35 mm, and/or other suitable amount of curvatures. The compound curvature may be, for example, a three-dimensional curvature in which the surface(s) have non-zero radii of curvature about two or more different axes (e.g., non-parallel axes, intersecting axes, non-intersecting axes, perpendicular axes such as the X-axis and Z-axis, etc.) and/or two or more different points within or behind device 10. If desired, one or more of the surfaces of the dielectric layer(s) in CGA 28 may be a developable surface. Display 18A may be a flexible display panel that is bent into a curved shape (e.g., a curved shape following the curved face of a user, a curved shape following the compound curvature of CGA 28, a curved shape characterized by inner and outer developable surfaces, etc.). The compound curvature may serve to provide device 10 with an attractive cosmetic appearance, may help device 10 to exhibit a compact and light weight form factor, may serve to maximize the mechanical strength of device 10, and/or may accommodate easy interaction with device 10 by the user, as examples.

During operation, device 10 may receive image data (e.g., image data for video, still images, etc.) and may present this information on displays 18B and/or 18A. Device 10 may also receive other data, control commands, user input, etc. Device 10 may also transmit data to accessories and other electronic equipment (e.g., external equipment 22 of FIG. 1). For example, image data from a forward-facing camera may be provided to an associated device, audio output may be provided to a device with speakers such as a headphone device, user input and sensor readings may be transmitted to remote equipment, etc.

Communications such as these may be supported using wired and/or wireless communications. In an illustrative configuration, wireless circuitry 16 (FIG. 1) may support wireless communications between device 10 and remote wireless equipment such as external equipment 22 of FIG. 1 (e.g., a cellular telephone, a wireless base station, a computer, headphones or other accessories, a remote control, peer devices, internet servers, and/or other equipment). Wireless communications may be supported using one or more antennas in device 10 and in the external equipment operating at one or more wireless communications frequencies. The antennas may be coupled to wireless transceiver circuitry. The wireless transceiver circuitry may include transmitter circuitry configured to transmit wireless communications signals using the antenna(s) and receiver circuitry configured to receive wireless communications signals using the antenna(s).

External equipment 22 of FIG. 1 may include at least a first accessory or peripheral device 22L and a second accessory or peripheral device 22R, as shown in the example of FIG. 2. Peripheral devices 22R and 22L may, for example, be control input devices (e.g., remote controls, gaming controllers, etc.) or audio output devices such as right and left speakers, right and left speakers of headphones worn by the user, etc. In implementations that are described herein as an example, peripheral device 22R is a right earbud and peripheral device 22L is a left earbud. Peripheral device 22R may therefore sometimes be referred to herein as right earbud 22R and peripheral device 22L may sometimes be referred to herein as left earbud 22L.

While operating device 10, the user wears device 10 on head 33. At the same time, the user wears left earbud 22L on and/or within their left ear (at the left side of head 33) and wears right earbud 22R on and/or within their right ear (at the right side of head 33). Earbuds 22L and 22R may each include a speaker, a battery, one or more processors, and wireless circuitry having one or more antennas. Earbuds 22L and 22R may be wireless earbuds having batteries that are rechargeable when earbuds 22L and 22R are plugged into a power adapter, placed on or within a charging dock, or placed within a charging case, for example.

One or more antennas in device 10 may transmit audio data in radio-frequency signals 24A to earbuds 22R and 22L. Earbuds 22L and 22R may play the audio data over the speakers in earbuds 22L and 22R. The audio data may include a first stream of audio data (e.g., left audio data) for playback by left earbud 22L and a second, different, stream of audio data (e.g., right audio data) for playback by right earbud 22R (e.g., to provide the user with stereo, three-dimensional, spatial, and/or surround sound). One or more antennas in device 10 may also convey other wireless data in radio-frequency signals 24W.

Additionally or alternatively, one or both of earbuds 22L and 22R may include one or more sensors that generate sensor data. The sensors may include a microphone, a touch sensor, a force sensor, an orientation sensor (e.g., a gyroscope, inertial measurement unit, motion sensor, etc.), an ambient light sensor, a proximity sensor, a magnetic sensor, a temperature sensor, and/or other sensors. The microphone may generate microphone data (e.g., voice data from the user speaking while wearing the earbuds). The touch sensor may generate touch sensor data and the force sensor may generate force sensor data (e.g., indicative of a user input provided to device 10 via the earbuds, indicative of the earbuds being presently located in the ears of the user, etc.). The ambient light sensor may generate ambient light sensor data (e.g., indicative of the location of device 10 and/or lighting conditions around the user). In general, the sensors may generate any desired sensor data. Earbuds 22L and 22R may transmit the sensor data to one or more antennas in device 10 using radio-frequency signals 24A and/or using radio-frequency signals 24W.

If care is not taken, components in device 10 can produce an excessive amount of heat. Displays 18B may, for example, be high resolution displays (e.g., 4K displays, 8K displays, or higher resolution displays) that consume a relatively high amount of power and therefore produce a relatively high amount of heat. Thermal management may be particularly important in device 10 because device 10 is worn on a user's head during operation, and care should be taken to ensure that device 10 does not become too hot or uncomfortable when worn by the user. Device 10 may include one or more fans such as fans 41 to help dissipate the thermal load of displays 18B and other components in device 10. Fans 41 may be mounted to logic board 38, for example. Device 10 may include a single fan 41 or multiple fans 41 (e.g., respective fans 41 overlapping the left display 18B and the right display 18B in device 10).

The housing for device 10 may include one or more thermal vents that allow fans 41 to circulate air into and out of device 10 (e.g., fans 41 may convey air through the vents). As used herein, the term “convey air” means the transmission (exhaust) and/or reception (intake) of air. For example, outer chassis 12A may include one or more thermal vents 39 aligned with one or more corresponding fans 41. Some vents 39 may be used for the intake of cool air (sometimes referred to herein as thermal intake vents) whereas other vents 39 are used for the exhaust of warm air (sometimes referred to herein as thermal exhaust vents). Vents 39 are sometimes also referred to herein as thermal ports 49 (e.g., intake ports and exhaust ports).

Each fan 41 may, for example, have at least one corresponding intake vent 39 and at least one corresponding exhaust vent 39. When driven, fan blades in fan 41 rotate, drawing cool air into device 10 through the intake vent. The cool air absorbs heat from displays 18B and/or other components on logic board 38 or elsewhere in device 10. The rotating fan blades of fan 41 push the heated air out of device 10 through the exhaust vent.

The intake vent and the exhaust vent may be located on opposing sides of device 10 if desired. This may help to prevent warm air expelled through the exhaust vent from being drawn back into the intake vent instead of cooler air. Disposing the intake vent along the bottom or cheek side of device 10 and the exhaust vent along the top or brow side of device 10 may, for example, help to prevent warm air output by the exhaust vent from rising towards the intake vent.

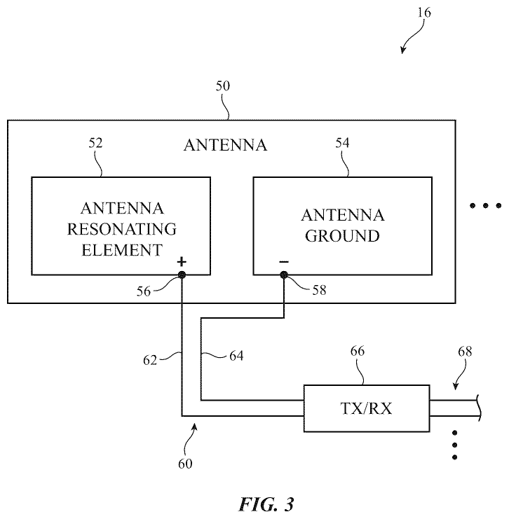

FIG. 3 is a diagram of illustrative components in wireless circuitry 16 of device 10. As shown in FIG. 3, wireless circuitry 16 may include one or more transceivers (e.g., transceiver circuitry) such as transceiver (TX/RX) 66. Transceiver 66 may handle transmission and/or reception of radio-frequency signals 24 (e.g., radio-frequency signals 24A or 24W of FIG. 2) within corresponding frequency bands at radio frequencies (sometimes referred to herein as communications bands or simply as bands).

The frequency bands handled by transceiver 66 may include wireless personal area network (WPAN) frequency bands such as the 2.4 GHz Bluetooth® band or other WPAN communications bands, cellular telephone communications bands such as a cellular low band (600-960 MHz), a cellular low-midband (1400-1550 MHz), a cellular midband (1700-2200 MHz), a cellular high band (2300-2700 MHz), a cellular ultra-high band (3300-5000 MHz), or other cellular communications bands between about 600 MHz and about 5000 MHz), 3G bands, 4G LTE bands, 3GPP 5G New Radio (NR) Frequency Range 1 (FR1) bands below 10 GHz, 3GPP 5G NR Frequency Range 2 (FR2) bands between 20 and 60 GHz, other centimeter or millimeter wave frequency bands between 10-300 GHz, sub-THz or THz bands between around 100-1000 GHz (e.g., 6G bands), wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), near-field communications frequency bands (e.g., at 13.56 MHz), satellite navigation frequency bands such as the Global Positioning System (GPS) bands, Global Navigation Satellite System (GLONASS) bands, and BeiDou Navigation Satellite System (BDS) bands, ultra-wideband (UWB) frequency bands that operate under the IEEE 802.15.4 protocol and/or other ultra-wideband communications protocols (e.g., a first UWB communications band at 6.5 GHz and/or a second UWB communications band at 8.0 GHz), communications bands under the family of 3GPP wireless communications standards, communications bands under the IEEE 802.XX family of standards, satellite communications bands, unlicensed bands such as an unlicensed band at 2.4 GHz and/or an unlicensed band between 5-6 GHZ, emergency and/or public services bands, and/or any other desired frequency bands of interest. Transceiver 66 may also be used to perform spatial ranging operations if desired (e.g., using a radar sensing scheme).

As shown in FIG. 3, wireless circuitry 16 may also include one or more antennas 50. Transceiver 66 may convey (e.g., transmit and/or receive) radio-frequency signals 24 using one or more antennas 50. Each antenna 50 may include one or more antenna conductors formed from conductive material such as metal. The antenna conductors may include one or more antenna conductors that form antenna resonating element 52 (sometimes referred to as an antenna resonator, an antenna radiator, or an antenna radiating element) and one or more antenna conductors that form antenna ground 54 (sometimes referred to as a ground plane).

Antenna 50 may have an antenna feed coupled between antenna resonating element 52 and antenna ground 54. The antenna feed may have a first (positive or signal) antenna feed terminal 56 coupled to antenna resonating element 52. The antenna feed may also have a second (ground or negative) antenna feed terminal 58 coupled to antenna ground 54. Antenna resonating element 52 may be separated from antenna ground 54 by a dielectric (non-conductive) gap. Antenna resonating element 52 and antenna ground 54 may be formed from separate pieces of metal or other conductive materials or may, if desired, be formed from separate portions of the same integral piece of metal. If desired, antenna 50 may include additional antenna conductors that are not coupled to antenna feed terminals 56 and 58 (e.g., parasitic elements). For some types of antennas (e.g., in implementations where antenna 50 is a slot antenna), the antenna resonating element may be formed from a slot in a single antenna conductor that is coupled to both antenna feed terminals 56 and 58 (e.g., where antenna feed terminals 56 and 58 are coupled to opposing sides of the slot).

Each antenna feed and thus each antenna 50 in wireless circuitry 16 may be coupled to one or more transceivers 66 in wireless circuitry 16 over a corresponding radio-frequency transmission line 60. Radio-frequency transmission line 60 may include a signal conductor such as signal conductor 62 (e.g., a positive signal conductor) and a ground conductor such as ground conductor 64. Ground conductor 64 may be coupled to antenna feed terminal 58 of antenna 50. Signal conductor 62 may be coupled to antenna feed terminal 56 of antenna 50. Radio-frequency transmission line 60 may include one or more of a stripline, microstrip, coaxial cable, coaxial probes, edge-coupled microstrip, edge-coupled stripline, waveguide, radio-frequency connector, combinations of these, etc. Radio-frequency transmission line 60 may also sometimes be referred to herein as a radio-frequency transmission line path. If desired, filter circuitry, tuning components, switching circuitry, impedance matching circuitry, phase shifter circuitry, amplifier circuitry, and/or other circuitry may be disposed on radio-frequency transmission line 60 and/or may be coupled between two or more of the antenna conductors in antenna 50.

The term “convey radio-frequency signals” as used herein means the transmission and/or reception of the radio-frequency signals (e.g., for performing unidirectional and/or bidirectional wireless communications with external wireless communications equipment). During transmission of radio-frequency signals 24, transceiver 66 transmits radio-frequency signals 24 (e.g., as modulated using wireless data such as audio data, control data, etc.) over radio-frequency transmission line 60. The radio-frequency signals may excite antenna currents to flow around the edges of antenna resonating element 52 and antenna ground 54 (via antenna feed terminals 56 and 58). The antenna currents may radiate radio-frequency signals 24 into free space (e.g., based at least on a resonance established by the radiating length of antenna resonating element 52 and/or antenna ground 54).

During the reception of radio-frequency signals 24 (e.g., as modulated by external equipment using wireless data such as voice data, sensor data, image data, etc.), incident radio-frequency signals 24 may excite antenna currents to flow around the edges of antenna resonating element 52 and antenna ground 54. The antenna currents may pass radio-frequency signals 24 to transceiver 66 over radio-frequency transmission line 60. Transceiver 66 may downconvert the radio-frequency signals to baseband and may demodulate wireless data from the signals (e.g., using baseband circuitry such as one or more baseband processors).

Antennas 50 may be formed using any suitable antenna structures. For example, antennas 50 may include antennas with antenna resonating elements that are formed from patch antenna structures (e.g., shorted patch antenna structures), slot antenna structures, loop antenna structures, stacked patch antenna structures, antenna structures having parasitic elements, inverted-F antenna structures, planar inverted-F antenna structures, helical antenna structures, monopole antenna structures, dipole antenna structures, Yagi (Yagi-Uda) antenna structures, surface integrated waveguide structures, hybrids of two or more of these designs, etc. If desired, one or more antennas 50 may be cavity-backed antennas. Antenna 50 may include one or more antenna conductors that form a parasitic antenna resonating element. Whereas antenna resonating element 52 is directly fed (e.g., via positive antenna feed terminal 56), parasitic antenna resonating elements are not directly fed (e.g., are indirectly fed by antenna resonating element 52) and/or serve to modify the radiation pattern and/or radiative characteristics of antenna 50. Two or more antennas 50 may be arranged in a phased antenna array if desired (e.g., for conveying centimeter and/or millimeter wave signals within a signal beam formed in a desired beam pointing direction that may be steered/adjusted over time). Earbuds 22R and 22L may also have wireless circuitry such as wireless circuitry 16 of FIG. 3.

Device 10 may include a first set of one or more antennas that convey radio-frequency signals 24A with earbuds 22R and 22L (FIG. 2). Device 10 may also include a second set of one or more antennas that convey radio-frequency signals 24W with other external equipment 22. Radio-frequency signals 24A may, for example, be conveyed through or towards rear side 32 of device 10, as shown in FIG. 2 (e.g., to and from the expected location of earbuds 22L and 22R while the user wears device 10). Radio-frequency signals 24W may be conveyed through front side 30 of device 10, through rear side 32, and/or through other sides of device 10. Radio-frequency signals 24A may be conveyed using a first radio access technology (RAT), a first communications protocol, a first transceiver in device 10, and/or a first set of frequencies or frequency bands. Radio-frequency signals 24W may be conveyed using a second RAT different from the first RAT, a second communications protocol different from the first communications protocol, a second transceiver in device 10 different from the first transceiver, and/or a second set of frequencies or frequency bands different from the first set of frequencies or frequency bands.

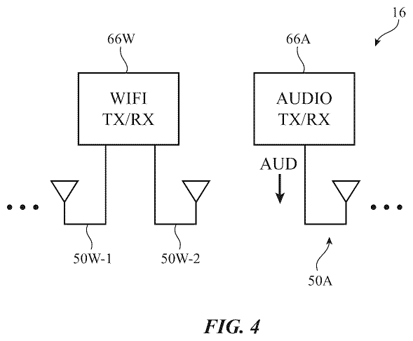

FIG. 4 is a diagram showing how wireless circuitry 16 may include different components for conveying radio-frequency signals 24A and 24W. As shown in FIG. 4, wireless circuitry 16 may use at least one antenna 50A to convey radio-frequency signals 24A and may use at least two antennas 50W (e.g., at least a first antenna 50W−1 and a second antenna 50W−2) to convey radio-frequency signals 24W (FIG. 2). While radio-frequency signals 24A may, in general, convey any desired wireless data between device 10 and multiple peripheral devices, an implementation in which radio-frequency signals 24A convey audio data and sensor data between device 10 and earbuds 22L and 22R is described herein as an example.

Antennas 50W−1 and 50 W−2 may be coupled to a first transceiver 66W over respective radio-frequency transmission lines. Antenna 50A may be coupled to a second transceiver 66A over a corresponding radio-frequency transmission line. Transceivers 66W and 66A may be formed using different respective radios, modems, chips, integrated circuits, integrated circuit (IC) packages, and/or modules. Transceiver 66W may convey radio-frequency signals 24W (FIG. 2) with external equipment other than earbuds 22R and 22L and/or with earbuds 22R and 22L using antennas 50W−1 and 50 W−2. Transceiver 66W may, for example, have respective first and second transmit chains and respective first and second receive chains (e.g., respective first and second ports) coupled to antennas 50W−1 and 50 W−2.

Transceiver 66W may convey radio-frequency signals 24W using at least a first communications protocol, at least a first RAT, and a first set of frequency bands. An implementation in which radio-frequency signals 24W include WLAN signals conveyed using a WLAN protocol (e.g., a Wi-Fi protocol), the WLAN RAT, and WLAN frequency bands is described herein as an example. If desired, radio-frequency signals 24W may also include Bluetooth signals conveyed using a Bluetooth protocol and Bluetooth frequency bands. Transceiver 66W may therefore sometimes be referred to herein as WLAN transceiver 66W, Wi-Fi transceiver 66W, or WLAN/Bluetooth transceiver 66W. Radio-frequency signals 24W may sometimes be referred to herein as WLAN or Wi-Fi signals 24W. This is merely illustrative and, in general, radio-frequency signals 24W may be conveyed using any desired protocol(s).

In some scenarios, Bluetooth signals conveyed by transceiver 66W are used to convey streams of audio data between device 10 and earbuds 22L and 22R. However, Bluetooth signaling can involve an excessive amount of latency and an excessive glitch rate. This can be disruptive to the user experience while listening to audio on earbuds 22L and 22R, particularly for audio data with a relatively high data rate (e.g., as may be required for immersive, high definition, three-dimensional audio presented to the user along with virtual reality content on displays 18B of FIG. 2). The high latency and excessive glitch rate associated with Bluetooth signaling may be caused by the Bluetooth protocol's requirement for time division duplexing between earbuds 22L and 22R (e.g., where audio data packets are transmitted to right earbud 22R and then to left earbud 22L in a time-alternating manner), frequency hopping between different Bluetooth frequencies, and a relatively large tolerance for packet retransmissions, for example.

To mitigate these issues, transceiver 66A may convey radio-frequency signals 24A (FIG. 2) using a second communications protocol, a second RAT, and a second set of frequency bands different from those used by transceiver 66W. For example, transceiver 66A may convey radio-frequency signals 24A using a non-Bluetooth, ultra-low-latency audio (ULLA) communications protocol optimized to support low latency and high data rate audio streaming from device 10 to earbuds 22L and 22R. Radio-frequency signals 24A may be conveyed in different frequency bands than radio-frequency signals 24W. For example, radio-frequency signals 24A may be conveyed using an unlicensed band at 2.4 GHz and/or an unlicensed band between 5-6 GHz. The band between 5-6 GHz may allow for a larger bandwidth than the 2.4 GHz band. In addition, the band between 5-6 GHz may allow for fewer coexistence/interference issues than the 2.4 GHz band, which coexists with the Bluetooth band, household appliances such as microwaves that emit around 2.4 GHz, etc.

The ultra-low-latency audio protocol may involve communications without performing time division duplexing between earbuds 22L and 22R and may involve communications with a lower packet re-transmission count limit, lower latency, lower glitch rate (e.g., 1 glitch per hour or fewer), more stability, and less interference than the Bluetooth protocol. Further, the ultra-low-latency audio protocol requires both earbuds 22R and 22L to convey radio-frequency signals 24A directly with device 10 rather than relaying signals or data between earbuds 22R and 2L and has a wireless fading channel selected to have a tighter distribution and shorter tail at the low power end than the Bluetooth protocol. Transceiver 66A may therefore sometimes be referred to herein as audio transceiver 66A. Radio-frequency signals 24A may sometimes be referred to herein as audio signals 24A. The example in which transceiver 66A conveys audio data is merely illustrative and, in general, transceiver 66A may use radio-frequency signals 24A to convey any desired wireless data.

During transmission, transceiver 66A may transmit audio data AUD in radio-frequency signals 24A (e.g., radio-frequency signals 24A may be modulated to carry audio data AUD). Antenna 50A may transmit the radio-frequency signals 24A including audio data AUD. Audio data AUD may include a stream of audio data packets. The stream of audio data packets may include a first set of audio data packets (or any desired first portion of the stream of audio data as distributed across one or more packets) for playback by left earbud 22L (e.g., a stream of left speaker audio data). The stream of audio data packets may also include a second set of audio data packets (or any desired second portion of the stream of audio data as distributed across one or more packets) for playback by right earbud 22R (e.g., a stream of right speaker audio data). The first and second sets may be interspersed or interleaved in time, for example.

Since the ultra-low-latency audio communications protocol governing transmission of radio-frequency signals 24A does not involve time division duplexing (TDD) between earbuds 22R and 22L, the same audio data AUD (e.g., the stream of audio data packets including both left and right speaker audio data) is concurrently (e.g., simultaneously) transmitted to both earbuds 22R and 22L and is concurrently received by both earbuds 22R and 22L. The controllers on earbuds 22R and 22L may demodulate the received audio data to recover the first and second sets of audio data packets. Left earbud 22L may then play the first set of audio data packets without playing (e.g., while discarding) the received second set of audio data packets. Right earbud 22R may play the second set of audio data packets without playing (e.g., while discarding) the received first set of audio data packets. Earbuds 22L and 22R may also transmit radio-frequency signals 24A to antenna 50A on device 10 to confirm/acknowledge receipt of audio data AUD, to convey voice/sensor data to device 10, etc. Since the sensor data gathered by earbuds 22R and 22L may not be subject to the same strict latency requirements as the audio data conveyed by transceiver 66A, earbuds 22L and 22R may, if desired, include additional wireless circuitry that transmits some or all of the sensor data to device 10 using the Bluetooth protocol or other protocols.

In some situations, using the same antenna 50A to convey radio-frequency signals 24A with both earbuds 22R and 22L can cause an excessive glitch rate due to random transmission nulls and the fading channel between antenna 50A and the earbuds. To improve link quality and glitch rate, wireless circuitry 16 may include different respective antennas 50A for conveying radio-frequency signals 24A with earbuds 22R and 22L, if desired.

Given the compact and lightweight form factor of device 10 and the presence of conductive structures in device 10 such as outer chassis 12A, inner chassis 12B, conductive portions of logic board 38, displays 18B, and display 18A, it can be challenging to place antennas 50 at locations device 10 that allow the antennas to exhibit satisfactory levels of radio-frequency performance. To help maximize the wireless performance of antennas 50 without increasing the size or weight of device 10, one or more of the antennas 50 in device 10 may be slot antennas having slot antenna resonating elements formed from outer chassis 12A.

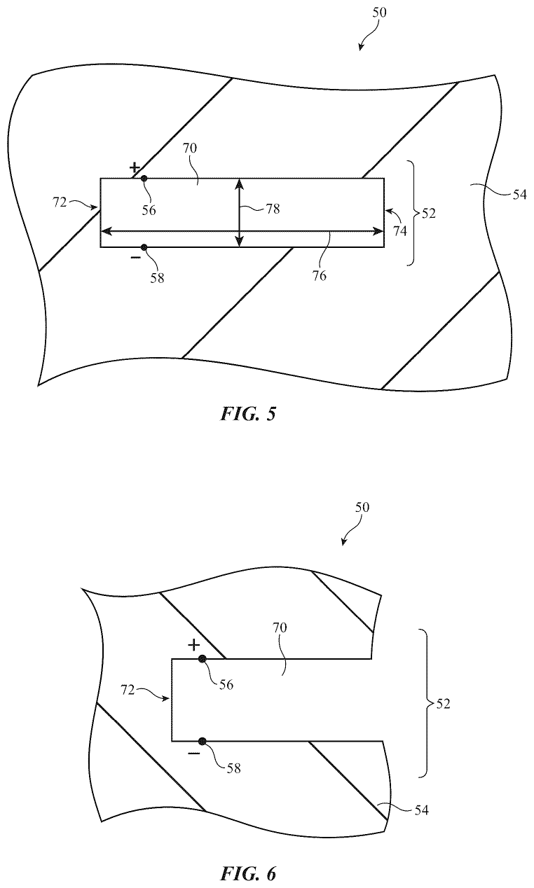

An illustrative slot antenna structure that may be used for forming antenna 50 is shown in FIG. 5. As shown in FIG. 5, antenna 50 may be a slot antenna having a slot antenna resonating element formed from slot 70 in antenna ground 54. Antenna ground 54 may include outer chassis 12A (FIG. 2) and, if desired, other ground structures within device 10. Slot 70 is sometimes also referred to herein as slot element 70, slot antenna resonating element 70, slot antenna radiating element 70, radiating slot 70, or resonating slot 70.

In the configuration of FIG. 5, slot 70 is a closed slot because antenna ground 54 (e.g., outer chassis 12A of FIG. 2) completely surrounds and encloses slot 70. Slot 70 may have an elongated length 76 (e.g., from end 72 to end 74) and an orthogonal width 78 that is less than length 76. The antenna feed for antenna 50 may be coupled across slot 70. For example, positive antenna feed terminal 56 and ground antenna feed terminal 58 may be coupled to antenna ground 54 at opposing edges of slot 70.

In general, the frequency response of an antenna is related to the size and shapes of the conductive structures in the antenna. Slot antennas of the type shown in FIG. 5 tend to exhibit response peaks when the perimeter of slot 70 is approximately equal to the wavelength of operation of antenna 50 (e.g. where the perimeter is equal to two times length 76 plus two times width 78). Antenna currents may flow between antenna feed terminals 56 and 58 around the perimeter of slot 70. As an example, when length 76>>width 78, the length of antenna 50 will tend to be about half of the length of other types of antennas such as inverted-F antennas configured to handle signals at the same frequency. Given equal antenna volumes, the slot antenna will therefore be able to handle signals at approximately twice the frequency of other antennas such as inverted-F antennas, for example. In addition, implementing antenna 50 as a slot antenna may eliminate the need for grounding other metal around antenna 50, thereby allowing integration of antenna 50 into outer chassis 12A (FIG. 2) without requiring additional grounding structures, which can consume excessive space in device 10.

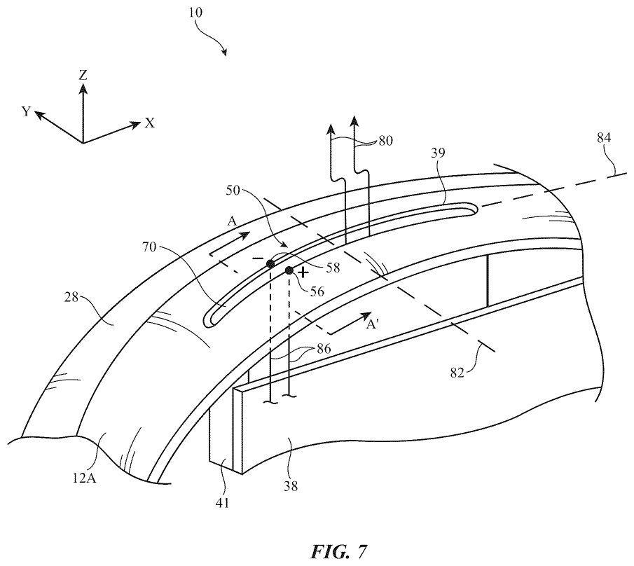

The example of FIG. 5 is merely illustrative. In general, slot 70 may have any desired shape. For example, slot 70 may have a meandering shape with different segments extending in different directions, may have straight and/or curved edges, etc. If desired, slot 70 may be an open slot (e.g., antenna 50 may be an open slot antenna). FIG. 6 is a diagram showing one example of how slow 70 may be an open slot. As shown in FIG. 6, slot 70 has an open end opposite end 72 (e.g., slot 70 is not surrounded by antenna ground 54 or extends through antenna ground 70 on one side).

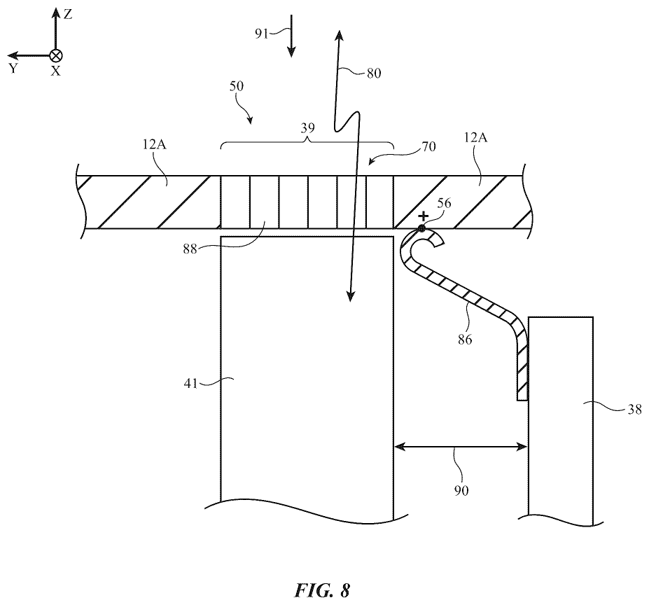

The slot 70 in antenna 50 may be formed from any desired opening in outer chassis 12A of device 10 (FIG. 2). As one example, slot 70 may be formed from a vent 39 (FIG. 2) in outer chassis 12A. FIG. 7 is a rear perspective view showing how slot 70 may be formed from a vent 39 in chassis 12A. In the example of FIG. 7, the rear housing or cover of device 10 and displays 18B of FIG. 2 have been omitted for the sake of clarity.

As shown in FIG. 7, fan 41 may be disposed within device 10 and aligned with a corresponding vent 39 in outer chassis 12A. CGA 28 may be mounted to outer chassis 12A (e.g., at the front face of device 10). Fan 41 may include a fan cavity defined by a corresponding fan housing (sometimes also referred to as a fan bracket). Fan 41 may be mounted to logic board 38 or to another structure in device 10. Fan 41 may include fan blades disposed within the fan cavity and one or more tunnels (sometimes also referred to as ventilation tunnels, ventilation shafts, shafts, or (elongated) segments/portions of the fan cavity or fan housing). One of the tunnels may extend from the fan blades to vent 39 in outer chassis 12A.

Controller(s) 20 (FIG. 1) may provide electrical signals that drive the fan blades in fan 41. The electrical signals may be adjusted to adjust the rotational speed of the fan blades. Vent 39 may be an intake vent or an exhaust vent. When the fan blades rotate around axis, the fan blades draw air into the fan cavity through vent 39 or push air out of the fan cavity through vent 39, as shown by arrows 80.

In practice, it may be desirable for fan 41 to be as large as possible to maximize cooling efficiency. However, if care is not taken, the presence of metal in fan 41 can limit the volume of and/or can electromagnetically block one or more of the antennas in device 10. To mitigate these issues, vent 39 may form slot 70 (e.g., the slot antenna resonating element) for a corresponding slot antenna such as antenna 50.

As shown in FIG. 7, antenna 50 may include antenna feed terminals 58 and 56 coupled to the interior surface of outer chassis 12A on opposing sides/edges of vent 39 (slot 70). As such, outer chassis 12A may form the antenna ground 54 for antenna 50 (FIGS. 5 and 6). Antenna feed terminals 58 and 56 may convey antenna current around the perimeter of vent 39 (slot 70) to convey radio-frequency signals to and/or from free space. Antenna 50 may convey radio-frequency signals using slot 70 while slot 70 (vent 39) concurrently passes air into fan 41 or out of fan 41.

If desired, outer chassis 12A may exhibit a curvature (e.g., a three-dimensional curvature) at or overlapping slot 70. For example, the portion of outer chassis 12A having vent 39 and thus slot 70 may lie in a three-dimensionally curved surface (e.g., a surface that is bent around multiple axes such as axes 82 and 84, which may be orthogonal or non-parallel). Curving slot 70 in this way may, for example, help to expand the radiation pattern and thus the coverage of antenna 50. Alternatively, slot 70 may be planar (e.g., located in a plane). By integrating antenna 50 into vent 39 in this way, antenna 50 may be disposed at an exterior of device 10 where the antenna is not blocked by other conductive components in fan 41 or device 10 and antenna 50 may be integrated into device 10 without requiring additional space or volume to fit the antenna resonating element.

The example of FIG. 7 is merely illustrative. If desired, one or more (e.g., all) of the vents 39 in outer chassis 12A may be used to form different slots 70 in respective antennas 50. Slot 70 may have other shapes. If desired, slot 70 may be an open slot (e.g., as shown in FIG. 6) having an open end that extends to CGA 28 or opposite CGA 28.

Antenna feed terminals 56 and 58 may be coupled to respective conductive interconnect structures 86. Conductive interconnect structures 86 may form part of the radio-frequency transmission line for antenna 50 and may couple antenna feed terminals 56 and 58 to transceiver circuitry in device 10. Conductive interconnect structures 86 may, for example, couple antenna feed terminals 56 and 58 to conductive traces on logic board 38. The conductive traces may be coupled to the transceiver circuitry for antenna 50 (e.g., on logic board 38 or another printed circuit board in device 10). Conductive interconnect structures 86 may include one or more conductive springs, conductive brackets, conductive clips, conductive springs, welds, solder, conductive adhesive, conductive foam, conductive fingers, conductive screws, conductive wire, conductive gaskets, conductive traces (e.g., on a flexible printed circuit), and/or other conductive structures.

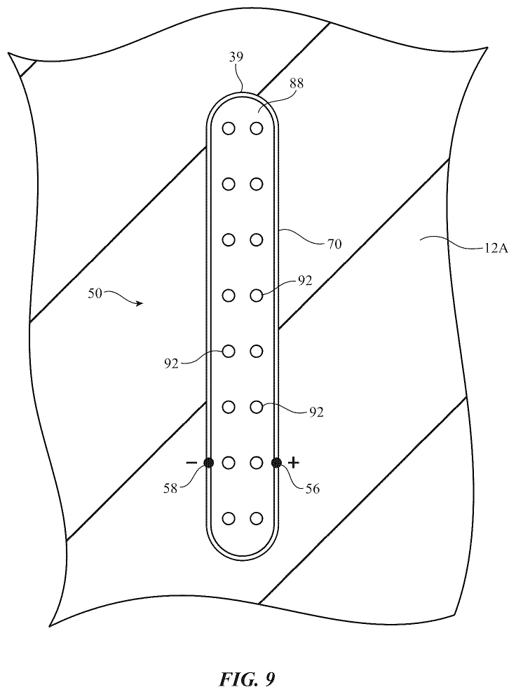

FIG. 8 is a cross-sectional side view (e.g., taken in the direction of line AA′ of FIG. 7) showing one example in which conductive interconnect structure 86 includes a conductive spring. As shown in FIG. 8, fan 41 (e.g., a tunnel in the fan housing for fan 41) may overlap and extend to vent 39 (slot 70) in outer chassis 12A. Fan 41 may convey air into or out of the interior of device 10 through vent 39, as shown by arrow 80.

If desired, device 10 may include a breathable protective covering such as covering 88 disposed within vent 39 (slot 70). Covering 88 may, for example, be formed from fabric, mesh, plastic, rubber, or other materials having openings that allow air to pass through vent 39 but that otherwise minimize or prevent the ingress of moisture, dust, and/or other contaminants into the interior of device 10.

As shown in FIG. 8, conductive interconnect structure 86 may include a conductive spring that couples positive antenna feed terminal 56 on outer chassis 12A (e.g., at or adjacent to an edge of slot 70) to logic board 38 (e.g., to conductive signal traces on logic board 38 that form part of the signal conductor for the radio-frequency transmission line for antenna 50). The conductive spring may, for example, be formed from a bent or folded elongated metal member such as a sheet metal member. The conductive spring may, for example, allow slot 70 to be fed at positive antenna feed terminal 56 while allowing logic board 38 to be offset from fan 41 by distance 90 (e.g., accommodating the large size of fan 41). Distance 90 may be relatively small or equal to zero in implementations where fan 41 is mounted to logic board 38. This example is merely illustrative and, in general, conductive interconnect structure 86 may include any desired conductive interconnect structure(s).

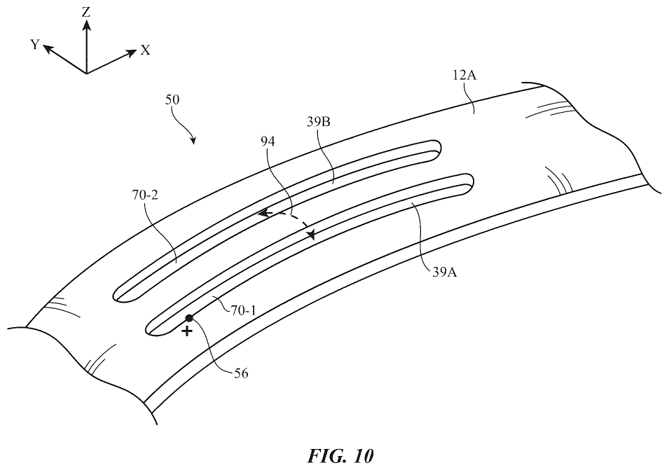

FIG. 9 is a top view of vent 39 (slot 70) (e.g., as viewed in the direction of arrow 91 of FIG. 8). As shown in FIG. 9, vent 39 may be filled with covering 88. Covering 88 may include a set of holes or openings 92 that allow the air driven by fan 41 to pass into or out of device 10 through vent 39. Openings 92 may have any size and/or shape (e.g., sufficiently large to allow air passage but sufficiently small to prevent the ingress of dust or other contaminants). Covering 88 may include any desired number of openings 92. Covering 88 may be formed from dielectric material (e.g., plastic, rubber, silicone, ceramic, etc.) that does not short or disrupt antenna current flowing around the perimeter of slot 70 between antenna feed terminals 56 and 58. The dielectric constant of covering 88 is greater than that of air. This may, for example, allow for a reduction in the size of slot 70 relative to implementations where slot 70 is filled with air, while still allowing antenna 50 to convey radio-frequency signals at the same frequency.

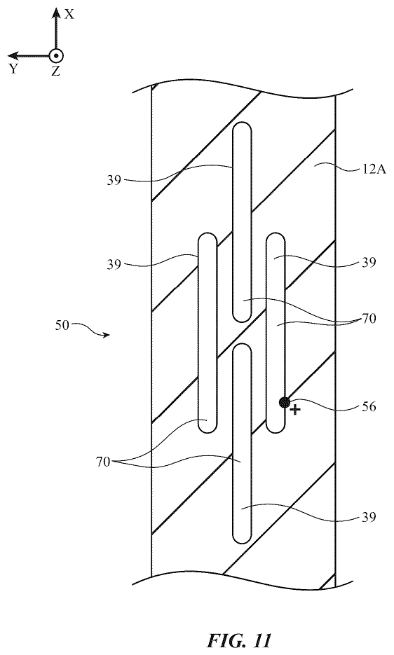

The example of FIGS. 7-9 in which the antenna resonating element for antenna 50 includes only a single slot 70 (vent 39) in outer chassis 12A is merely illustrative. If desired, the antenna resonating element for antenna 50 may include multiple vents 39 (slots 70) in outer chassis 12A. FIG. 10 is a perspective view showing one example of how the antenna resonating element for antenna 50 may include multiple vents 39 (slots 70) in outer chassis 12A.

As shown in FIG. 10, outer chassis 12A may include multiple vents 39 overlapping the underlying fan 41 (FIG. 7) such as at least a first vent 39A and a second vent 39B. Vent 39A may form a first slot antenna resonating element 70-1 for antenna 50. Vent 39B may form a second slot antenna resonating element 70-2 for antenna 50.

Vent 39A may be a directly fed slot antenna resonating element for antenna 50. As such, positive antenna feed terminal 56 may be coupled to an edge of vent 39A. Antenna currents conveyed around the perimeter of vent 39A may produce (e.g., via near-field electromagnetic coupling 94) corresponding antenna currents that flow around vent 39B. In this way, vent 39B may form an indirectly fed slot antenna resonating element for antenna 50 (e.g., where the directly fed vent 39A feeds the indirectly fed vent 39B). Implementing antenna 50 using two slot antenna resonating elements 70-1 and 70-2 may allow each slot antenna resonating element to have a narrower width (e.g., 2-5 mm) than in implementations where antenna 50 and fan 41 include only a single vent 39. To allow for the same amount of air flow, the total area of vents 39A and 39B may be the same as the area of vent 39 of FIGS. 7-9.

The example of FIG. 10 is merely illustrative. Slot antenna resonating elements 70-1 and 70-2 may be at least partially overlapping (e.g., when viewed in the +Y direction) and/or may be at least partially non-overlapping. Slot antenna resonating elements 70-1 and 70-2 may have the same shape and/or size or may have different shapes and/or sizes. Providing slot antenna resonating elements 70-1 and 70-2 with different sizes (perimeters) may configure each slot antenna resonating element to contribute different frequencies to the overall frequency response of antenna 50 (e.g., broadening the bandwidth of antenna 50).

In general, antenna 50 may include any desired number of antenna resonating elements formed from any desired number of at least partially overlapping vents 39 in outer chassis 12A. FIG. 11 shows one example in which antenna 50 includes slot antenna resonating elements formed from four overlapping vents 39 in outer chassis 12A. One or more of the vents may be directly fed (e.g., by positive antenna feed terminal 56) whereas the remainder of the vents are indirectly fed. To allow for the same amount of air flow, the sum of the areas of each of the vents 39 in antenna 50 (FIG. 11) may be the same as the area of vent 39 of FIGS. 7-9.

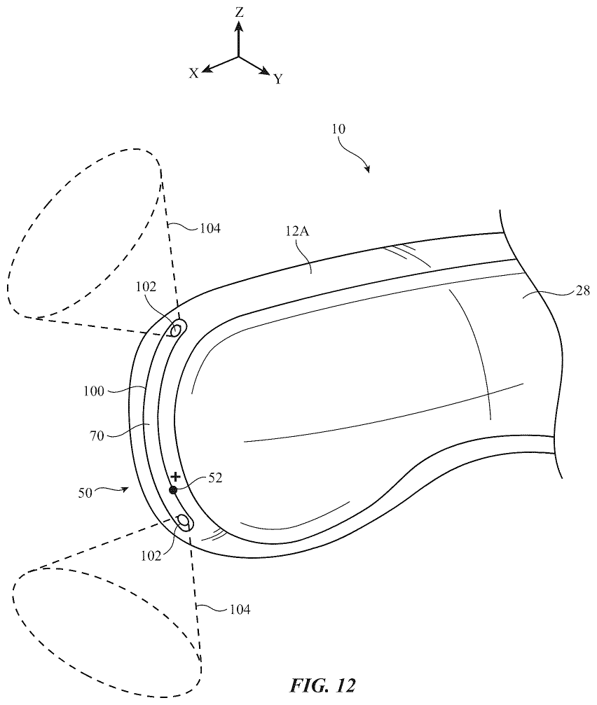

The example of FIGS. 7-11 in which the slot(s) 70 of antenna 50 are formed from vents 39 in outer chassis 12A is merely illustrative. In general, the slot(s) 70 of antenna 50 may be formed from any desired slots, notches, gaps, or openings in outer chassis 12A. As another example, slot 70 may be formed from a sensor window in outer chassis 12A. FIG. 12 is a perspective front view showing one example of how slot 70 may be formed from a sensor window in outer chassis 12A.

As shown in FIG. 12, outer chassis 12A may include a sensor window such as sensor window 100. In the example of FIG. 12, sensor window 100 is disposed at the right side of outer chassis 12A. In general, sensor window 100 may be disposed at any desired location along outer chassis 12A. Sensor window 100 may be formed from a slot or opening in outer chassis 12A. The slot may be filled with dielectric material (e.g., a dielectric cover layer or sensor window). The dielectric material may be plastic, glass, sapphire, ceramic, or other dielectrics. If desired, sensor window 100 may lie in a three-dimensionally curved surface (e.g., as given by the curvature of the corresponding portion of outer chassis 12A).

Device 10 may include one or more sensors 102 overlapping and/or aligned with sensor window 100. Each sensor 102 may have a corresponding field of view 104. Each sensor 102 may gather sensor data from within its field of view 104. One or more of sensors 102 may be, for example, an optical or light-based sensor such as an image sensor (e.g., a camera), a light detection and ranging (lidar) sensor, or an ambient light sensor. The light-based sensor may receive light through sensor window 100 from within its field of view 104 (e.g., sensor 102 may capture images or image sensor data through sensor window 100, may gather lidar data through sensor window 100, may gather ambient light levels through sensor window 100, etc.). The light-based sensor generates sensor data in response to the received light. Additionally or alternatively, the light-based sensor may transmit light through sensor window 100 within its field of view 104 (e.g., sensor 102 may include one or more optical emitters and/or one or more optical sensors). Some of the light received through sensor window 100 may include a reflected version of the transmitted light if desired (e.g., light that has reflected off one or more external objects). The transmitted light may include infrared light and/or visible light (e.g., for use in ranging, lidar sensing, face mapping, facial recognition, orientation sensing, gesture sensing, etc.). Sensor window 100 may be substantially transparent to the light conveyed by sensor(s) 102.

Additionally or alternatively, one or more of sensors 102 may be a radio-frequency (RF) sensor such as a radar sensor or a voltage standing wave ratio (VSWR) sensor. The radio-frequency sensor may transmit radio-frequency signals (e.g., radar signals) through sensor window 100 within its field of view 104 and/or may receive radio-frequency signals (e.g., reflected radar signals) through sensor window 100 within its field of view 104. Additionally or alternatively, one or more of sensors 102 may be a thermal sensor that measures heat through sensor window 100 within field of view 104.

Device 10 may perform any desired operations based on the sensor data gathered by sensor(s) 102. For example, the controller on device 10 may detect a corresponding user input or gesture based on the sensor data, may adjust one or more displays in device 10 based on the sensor data, may detect an orientation of device 10 based on the sensor data, may detect the presence, position, and/or orientation of one or more other objects, devices, users, people, or animals based on the sensor data, may map the environment or surroundings of device 10, may record spatial audio based on the sensor data, may record voice data based on the sensor data, may identify ambient conditions based on the sensor data, etc.

Each sensor 102 may be provided with a different respective sensor window 100 or, if desired, a single sensor window 100 may overlap two or more sensors 102. The curvature of outer chassis 12A and sensor window 70 may allow multiple sensors 102 to be provided at different orientations to maximize the cumulative field of view across the sensors (e.g., given by the combination of each field of view 104).

As shown in FIG. 12, sensor window 100 may form the slot antenna resonating element (e.g., slot 70) for antenna 50. As such, the positive antenna feed terminal 52 for antenna 50 may be coupled to an edge of sensor window 100 (slot 70). Positive antenna feed terminal 52 may convey antenna currents around sensor window 100. Sensor window 100 may convey corresponding radio-frequency signals for antenna 50 (e.g., as a slot antenna resonating element).

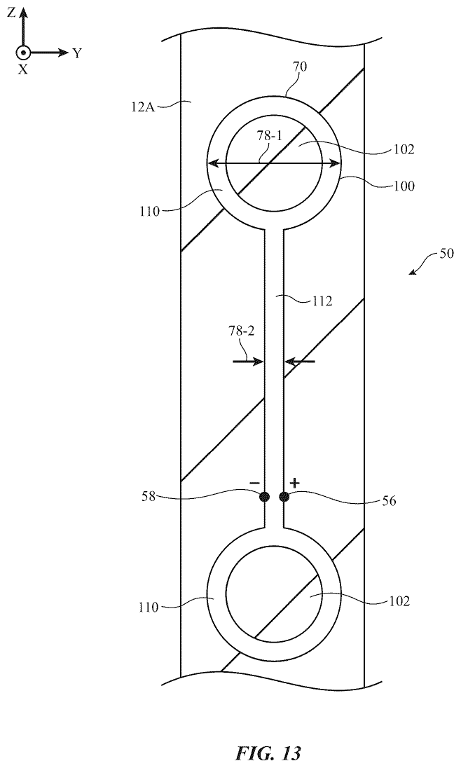

If desired, sensor window 100 may have a uniform width along its length or may have different widths at different locations along its length. FIG. 13 is a diagram showing one example of how sensor window 100 may have different widths at different locations along its length. As shown in FIG. 13, sensor window 100 may include an elongated (narrowed) portion (segment) 112 having width 78-2. Sensor window 100 may have enlarged portions (segments) 110 at either end of elongated portion 112. Each enlarged portion 110 may have a width 78-1 greater than width 78-2. Enlarged portions 110 may be circular, rectangular, or other shapes. Each enlarged portion 110 may overlap a corresponding sensor 102. Enlarged portions 110 are sometimes also referred to herein as enlarged ends 110 or simply ends 100 of sensor window 100.

The antenna feed terminals 56 and 58 for antenna 50 may be coupled across elongated portion 112 of sensor window 100. Alternatively, the antenna feed terminals may be coupled across an enlarged portion 110. Narrowing sensor window 100 between enlarged portions 110 in this way may help to hide sensor window 100 from view and/or may help to maximize the amount of conductive material in outer chassis 12A between sensors 102, which serves to maximize the mechanical strength of outer chassis 12A. At the same time, the total perimeter of sensor window 100 may be selected to configure antenna 50 to convey radio-frequency signals in a corresponding frequency band.

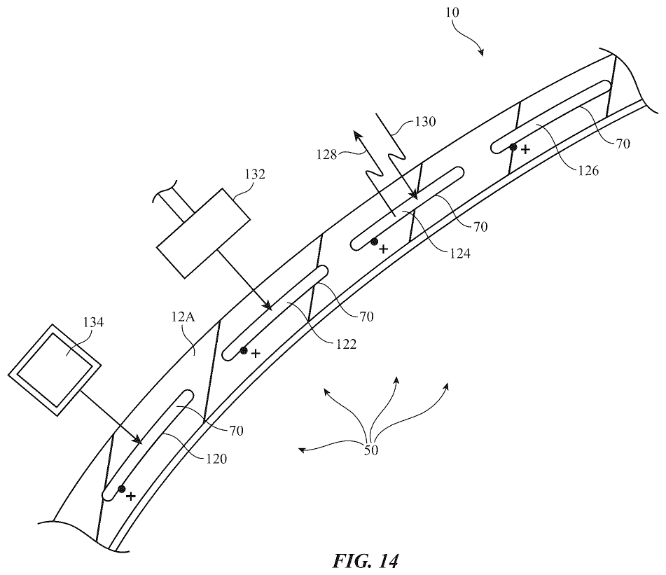

FIG. 14 is a perspective view of outer chassis 12A illustrating other slots in outer chassis 12A that may be used to form the slot antenna resonating element (slot 70) of one or more antennas 50. As shown in FIG. 14, outer chassis 12A may include a card receiving port 120. Card receiving port 120 may receive a card 134 (e.g., a subscriber identity module (SIM) card, a data or memory card such as an SD card or micro SD card, etc.). Card receiving port 120 may form the slot 70 of a corresponding antenna 50 if desired. Card receiving port 120 may sometimes also be referred to as a memory card port, a data card port, or a SIM card port.

Additionally or alternatively, outer chassis 12A may include a power receiving port 122 (sometimes also referred to herein as charging port 122 or power port 122). Power receiving port 122 may receive a power cable 132 (e.g., a charging cable, a cable that carries both power and data lines, a universal serial bus (USB) cable, a power adapter, etc.). Power cable 132 may provide power and/or data to device 10 while plugged into power receiving port 122. Power receiving port 122 may form the slot 70 of a corresponding antenna 50 if desired.

Additionally or alternatively, outer chassis 12A may include an acoustic port 124. Acoustic port 124 may emit sound (acoustic signals) 130 into the environment and/or may receive/sense sound 128 (acoustic signals) from the environment. Acoustic port 124 may be, for example, a speaker port for a speaker in device 10, a microphone port for a microphone or sound sensor in device 10, an ultrasonic port for an ultrasonic transmitter and/or receiver in device 10, barometric port, etc. Acoustic port 124 may form the slot 70 of a corresponding antenna 50 if desired.

Additionally or alternatively, outer chassis 12A may include a button opening 126. Device 10 may include a dielectric button member (e.g., of a volume button, a power button, a display adjustment button, a button that adjusts device 10 between a virtual, mixed, and/or augmented reality display modes, etc.) and/or touch sensor surface within button opening 126. A user may press the dielectric button member to provide a corresponding user input to device 10 (e.g., through button opening 126). Button opening 126 may form the slot 70 of a corresponding antenna 50 if desired.

In general, the slot(s) 70 in antenna 50 may be formed from any desired opening(s) in outer chassis 12A. Outer chassis 12A may include different types of openings that form slots 70 of multiple different antennas 50 (e.g., at or along different sides of device 10). Slots 70 may have any desired shape and may be closed slots (e.g., as shown in FIGS. 5 and 7-14) or open slots (e.g., as shown in FIG. 6). Slots 70 need not be formed in outer chassis 12A and, in general, any of the slots 70 described herein may be formed in any desired conductive structures in device 10 such as other conductive portions of the housing for device 10, conductive structures in CGA 28, etc.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

Devices such as device 10 may gather and/or use personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

Physical environment: A physical environment refers to a physical world that people can sense and/or interact with without aid of electronic systems. Physical environments, such as a physical park, include physical articles, such as physical trees, physical buildings, and physical people. People can directly sense and/or interact with the physical environment, such as through sight, touch, hearing, taste, and smell.

Computer-generated reality: in contrast, a computer-generated reality (CGR) environment refers to a wholly or partially simulated environment that people sense and/or interact with via an electronic system. In CGR, a subset of a person's physical motions, or representations thereof, are tracked, and, in response, one or more characteristics of one or more virtual objects simulated in the CGR environment are adjusted in a manner that comports with at least one law of physics. For example, a CGR system may detect a person's head turning and, in response, adjust graphical content and an acoustic field presented to the person in a manner similar to how such views and sounds would change in a physical environment. In some situations (e.g., for accessibility reasons), adjustments to characteristic(s) of virtual object(s) in a CGR environment may be made in response to representations of physical motions (e.g., vocal commands). A person may sense and/or interact with a CGR object using any one of their senses, including sight, sound, touch, taste, and smell. For example, a person may sense and/or interact with audio objects that create 3D or spatial audio environment that provides the perception of point audio sources in 3D space. In another example, audio objects may enable audio transparency, which selectively incorporates ambient sounds from the physical environment with or without computer-generated audio. In some CGR environments, a person may sense and/or interact only with audio objects. Examples of CGR include virtual reality and mixed reality.

Virtual reality: A virtual reality (VR) environment refers to a simulated environment that is designed to be based entirely on computer-generated sensory inputs for one or more senses. A VR environment comprises a plurality of virtual objects with which a person may sense and/or interact. For example, computer-generated imagery of trees, buildings, and avatars representing people are examples of virtual objects. A person may sense and/or interact with virtual objects in the VR environment through a simulation of the person's presence within the computer-generated environment, and/or through a simulation of a subset of the person's physical movements within the computer-generated environment.

Mixed reality: In contrast to a VR environment, which is designed to be based entirely on computer-generated sensory inputs, a mixed reality (MR) environment refers to a simulated environment that is designed to incorporate sensory inputs from the physical environment, or a representation thereof, in addition to including computer-generated sensory inputs (e.g., virtual objects). On a virtuality continuum, a mixed reality environment is anywhere between, but not including, a wholly physical environment at one end and virtual reality environment at the other end. In some MR environments, computer-generated sensory inputs may respond to changes in sensory inputs from the physical environment. Also, some electronic systems for presenting an MR environment may track location and/or orientation with respect to the physical environment to enable virtual objects to interact with real objects (that is, physical articles from the physical environment or representations thereof). For example, a system may account for movements so that a virtual tree appears stationery with respect to the physical ground. Examples of mixed realities include augmented reality and augmented virtuality. Augmented reality: an augmented reality (AR) environment refers to a simulated environment in which one or more virtual objects are superimposed over a physical environment, or a representation thereof. For example, an electronic system for presenting an AR environment may have a transparent or translucent display through which a person may directly view the physical environment. The system may be configured to present virtual objects on the transparent or translucent display, so that a person, using the system, perceives the virtual objects superimposed over the physical environment. Alternatively, a system may have an opaque display and one or more imaging sensors that capture images or video of the physical environment, which are representations of the physical environment. The system composites the images or video with virtual objects, and presents the composition on the opaque display. A person, using the system, indirectly views the physical environment by way of the images or video of the physical environment, and perceives the virtual objects superimposed over the physical environment. As used herein, a video of the physical environment shown on an opaque display is called “pass-through video,” meaning a system uses one or more image sensor(s) to capture images of the physical environment, and uses those images in presenting the AR environment on the opaque display. Further alternatively, a system may have a projection system that projects virtual objects into the physical environment, for example, as a hologram or on a physical surface, so that a person, using the system, perceives the virtual objects superimposed over the physical environment. An augmented reality environment also refers to a simulated environment in which a representation of a physical environment is transformed by computer-generated sensory information. For example, in providing pass-through video, a system may transform one or more sensor images to impose a select perspective (e.g., viewpoint) different than the perspective captured by the imaging sensors. As another example, a representation of a physical environment may be transformed by graphically modifying (e.g., enlarging) portions thereof, such that the modified portion may be representative but not photorealistic versions of the originally captured images. As a further example, a representation of a physical environment may be transformed by graphically eliminating or obfuscating portions thereof. Augmented virtuality: an augmented virtuality (AV) environment refers to a simulated environment in which a virtual or computer generated environment incorporates one or more sensory inputs from the physical environment. The sensory inputs may be representations of one or more characteristics of the physical environment. For example, an AV park may have virtual trees and virtual buildings, but people with faces photorealistically reproduced from images taken of physical people. As another example, a virtual object may adopt a shape or color of a physical article imaged by one or more imaging sensors. As a further example, a virtual object may adopt shadows consistent with the position of the sun in the physical environment.

Hardware: there are many different types of electronic systems that enable a person to sense and/or interact with various CGR environments. Examples include head mounted systems, projection-based systems, heads-up displays (HUDs), vehicle windshields having integrated display capability, windows having integrated display capability, displays formed as lenses designed to be placed on a person's eyes (e.g., similar to contact lenses), headphones/earphones, speaker arrays, input systems (e.g., wearable or handheld controllers with or without haptic feedback), smartphones, tablets, and desktop/laptop computers. A head mounted system may have one or more speaker(s) and an integrated opaque display. Alternatively, a head mounted system may be configured to accept an external opaque display (e.g., a smartphone). The head mounted system may incorporate one or more imaging sensors to capture images or video of the physical environment, and/or one or more microphones to capture audio of the physical environment. Rather than an opaque display, a head mounted system may have a transparent or translucent display. The transparent or translucent display may have a medium through which light representative of images is directed to a person's eyes. The display may utilize digital light projection, OLEDs, LEDs, μLEDs, liquid crystal on silicon, laser scanning light sources, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface.

The foregoing is merely illustrative and various modifications can be made by those skilled in the art without departing from the scope and spirit of the described embodiments. The foregoing embodiments may be implemented individually or in any combination.

What is claimed is:

1. A head-mounted device comprising:
a first conductive chassis;
a logic board mounted to the first conductive chassis;
first and second displays mounted to the logic board and configured to display respective left and right images;
a second conductive chassis that extends around the first conductive chassis and the logic board;
a cover mounted to the second conductive chassis opposite the first and second displays, the cover having a third display configured to display images through the cover; and
an antenna having an antenna resonating element formed from a slot in the second conductive chassis.

2. The head-mounted device of claim 1, wherein the slot comprises a vent and the electronic device further comprises:
a fan configured to convey air through the vent.

3. The head-mounted device of claim 2, further comprising:
a conductive spring that couples the logic board to the second conductive chassis at an antenna feed terminal of the antenna.

4. The head-mounted device of claim 1, wherein the slot comprises a sensor window.

5. The head-mounted device of claim 4, further comprising:
a sensor overlapping the sensor window and configured to gather sensor data through the sensor window.

6. The head-mounted device of claim 5, wherein the sensor overlaps a first portion of the sensor window, the head-mounted device further comprising:
an additional sensor overlapping a second portion of the sensor window and configured to gather sensor data through the sensor window, wherein the sensor window has a third portion that couples the first portion to the second portion and the third portion is narrower than the first portion and the second portion.

7. The head-mounted device of claim 5, wherein the sensor comprises a camera configured to capture images through the sensor window.

8. The head-mounted device of claim 5, wherein the sensor comprises a light detection and ranging sensor.

9. The head-mounted device of claim 3, further comprising:
an optical emitter configured to emit light through the sensor window.

10. The head-mounted device of claim 9, wherein the light comprises infrared light.

11. The head-mounted device of claim 1, wherein the slot comprises a card port.

12. The head-mounted device of claim 1, wherein the slot comprises a charging port.

13. The head-mounted device of claim 1, wherein the slot comprises an acoustic port.

14. The head-mounted device of claim 1, wherein the slot comprises a button opening.

15. The head-mounted device of claim 1, wherein the slot lies in a three-dimensionally curved surface.

16. An electronic device comprising:
a conductive housing;
a vent in the conductive housing;
a fan configured to convey air through the vent; and
an antenna having antenna feed terminals coupled to the conductive housing on opposing sides of the vent.

17. The electronic device of claim 16, wherein the vent lies in a three-dimensionally curved surface.

18. The electronic device of claim 16, further comprising:
an additional vent in the conductive housing, wherein the fan is configured to convey the air through the additional vent and the additional vent forms an indirectly fed slot antenna resonating element of the antenna.

19. An electronic device comprising:
a conductive housing extending around a periphery of the electronic device;
a display mounted to the conductive housing;
a dielectric window in the conductive housing;
a first image sensor overlapping the dielectric window and configured to capture first image sensor data through the dielectric window;
a second image sensor overlapping the dielectric window and configured to capture second image sensor data through the dielectric window; and
an antenna having antenna feed terminals coupled to the conductive housing on opposing sides of the dielectric window.

20. The electronic device of claim 19, wherein the dielectric window lies in a three-dimensionally curved surface.
